(19) United States
(12) Patent Application Publication
(10) Pub. No.: US 2008/0191794 A1
(43) Pub. Date: Aug. 14, 2008

(54) METHOD AND APPARATUS FOR TUNING AN ACTIVE FILTER

(75) Inventors: Chinq-shiun Chiu, Hsinchu City (TW); Tze-yee Sin, Singapore (SG); Rawinder Dharmalinggam, Singapore (SG)

Correspondence Address: MADSON & AUSTIN, 15 WEST SOUTH TEMPLE, SUITE 900, SALT LAKE CITY, UT, 84101, US

(73) Assignee: MediaTek Inc., Hsin-Chu (TW)

(21) Appl. No.: 11/672,704

(22) Filed: Feb. 8, 2007

(51) Int. Cl. H03K 5/00; H02J 7/00

(52) U.S. Cl. 327/553; 320/166

(57) ABSTRACT

A method of tuning an RC time constant includes the steps of providing a predetermined time period value associated with a predetermined RC time constant, providing a DC reference signal, generating an second signal responsive to charging a capacitor until magnitudes of the second signal and the DC reference signal are matched, determining a charging time period of the capacitor, and adjusting a capacitance of the capacitor to comply with the predetermined RC time constant based on the time period and the predetermined time period value.

### BACKGROUND OF THE INVENTION

1. Field of the Invention

The present invention relates to an apparatus and related method for tuning an active filter, more particularly to an apparatus and related method for tuning the 3-dB corner frequency of filters to approach a constant characteristic.

2. Description of the Related Art

As development of integrated circuitry technology is accelerated, necessary functions are integrated within a single chip. In particular, analog filter circuits implemented by capacitors and resistors are widely used in electronics or communication products. In the design and manufacturing of active continuous-time filter, the frequency response is directly proportional to variation of the values of resistors and capacitors. As is well known in the art, the use of capacitors and resistors generates RC product shifts on account of variations in temperature, supply voltage and manufacturing process. Unavoidable variation in the manufacturing process and variations during operation causes resistance of a resistor with approximately ±21% deviation, and capacitance of capacitor with approximately ±10% deviation. In other words, active filters result in RC time constant deviations from the actual value of individual elements compared to their design value up to ±32%. As a result, tuning circuits may conventionally be used with analog filter circuits in order to fine tune or adjust the filter to compensate for variation in the analog components of the filter.

The employment of integrated active filter circuits in combination with external high precision resistors and capacitors to compensate for the above-mentioned variations is a solution to such problem. However, this solution conflicts with the advantages offered by integrated circuits, such as low cost and small form-factor (few or none external components) of the filter circuit. Therefore, it has become increasingly common to embed an automatic tuning circuit as part of a chip to calibrate the RC time constant deviation.

Traditionally, calibration of RC time constant is based on two invariant identities to temperature and process, bandgap voltage and a clock frequency. One way to achieve a tunable RC time constant is to provide active resistors, i.e. resistors fabricated as MOSFETs instead of passive resistor elements, and control the MOSFET to provide a desired resistance. In such an arrangement, a feedback circuit measures the actual RC time constant of the filter with reference to, a clock frequency, and provides a corresponding signal to the MOSFET to continuously adjust their resistance to attain the required time constant. This solution, however, necessitates a continuous input signal for the MOSFET and thus causes an increase of power consumption of the filter circuit. Moreover, this approach is disadvantageous when a low supply voltage is used (e.g. as low as 1 V), since the MOSFET, in general, requires a large sub-1V threshold voltage to be conductive, such that the MOSFET cannot provide a sufficient variable control range to compensate for the large variations of the active filter.

Accordingly, in order to solve such problem, there is a need for an improved method and apparatus for tuning an active filter.

### SUMMARY OF THE INVENTION

It is therefore a primary objective of this invention to provide a tuning method and apparatus for adjusting the capacitance of a capacitor to comply with the desired RC time constant.

Briefly summarized, the claimed invention provides a method of tuning an RC time constant comprising the steps of providing a predetermined time period value associated with a predetermined RC time constant, providing a DC reference signal, generating an AC signal responsive to charging a capacitor until magnitudes of the AC signal and the DC reference signal are matched, determining a charging time period of the capacitor, and adjusting a capacitance of the capacitor to comply with the predetermined RC time constant based on the charging time period and the predetermined time period value.

According to the claimed invention, a tuning circuit for tuning an active filter comprises a signal generator for generating a first signal and a second signal in proportion to the first signal, a variable capacitor, a comparator for comparing a charging voltage with the second signal, wherein a steady current generated based on the first signal serves to charge the variable capacitor to vary the charging voltage, a period determining unit for determining a time period during which the variable capacitor is charged, until the charging voltage matches the magnitude of the second signal, a target value storage unit for storing a target time period, and a capacitance calibrator for calibrating a capacitance of the variable capacitor based on the time period and the target time period.

According to the claimed invention, a method for tuning an RC time constant comprises the steps of: providing a steady current to charge a capacitor to a reference voltage, determining a charging time period, and adjusting a capacitance of the capacitor based on the charging time period. The time period is proportional to the RC time constant.

The disclosed inventions will be described with reference to the accompanying drawings, which show important sample embodiments of the invention and which are incorporated in the specification hereof by reference.

### BRIEF DESCRIPTION OF THE DRAWINGS

FIG. 1 shows a block diagram of a tuning circuit for tuning an RC circuitry in accordance with the present invention.

FIG. 2 shows a circuit diagram of a preferred embodiment of the tuning circuit depicted in FIG. 1.

FIG. 3 illustrates a timing diagram associated with reference voltage signal Vref (Vr) and voltage drop across variable capacitor Ca (Vc) depicted in FIG. 2.

FIG. 4 is an example of a lookup table illustrating a relationship of clock frequency and target count value for various communication systems.

FIG. 5 shows another embodiment of tuning circuit in accordance with the present invention.

FIG. 6 shows a flowchart of tuning the RC time constant according to the present invention.

FIG. 7 shows an example of a nominal design capacitance of a variable capacitor

### DETAILED DESCRIPTION OF THE PREFERRED EMBODIMENT

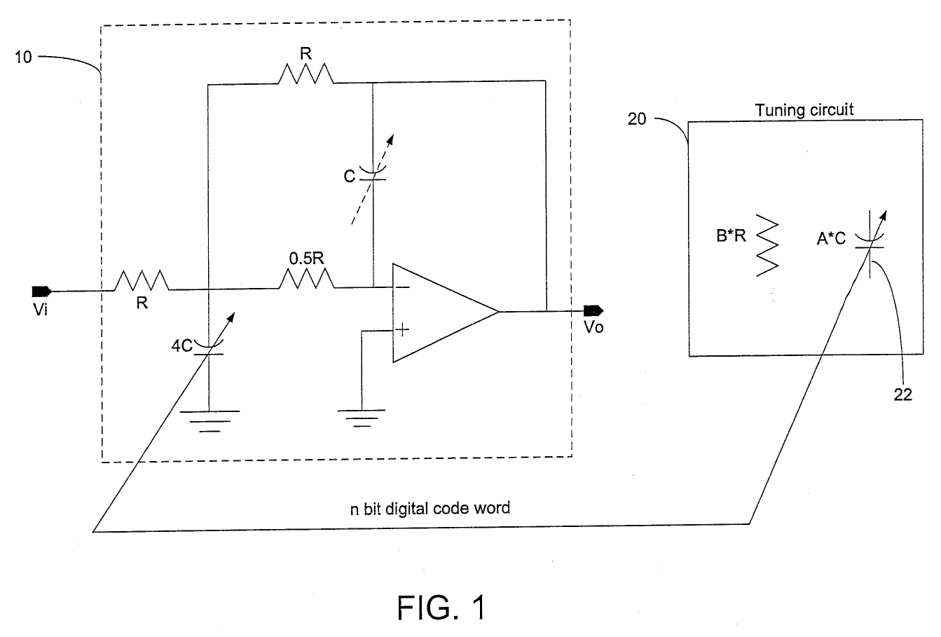

Referring to FIG. 1, as shown is a block diagram of a tuning circuit 20 for tuning an RC circuitry 10 in accordance with the present invention. The RC circuitry 10 comprises resistors and capacitors which are all made on a wafer and associated with a variable capacitor 22 of the tuning circuit 20. With good matching, each capacitance value of capacitors on the same wafer has almost identical error of capacitance. Thus the tuning circuit 20 can measure any capacitor on the wafer to determine the capacitance error and feedback such error to compensate for the capacitance of all other capacitors on the wafer to achieve the desired RC time constant.

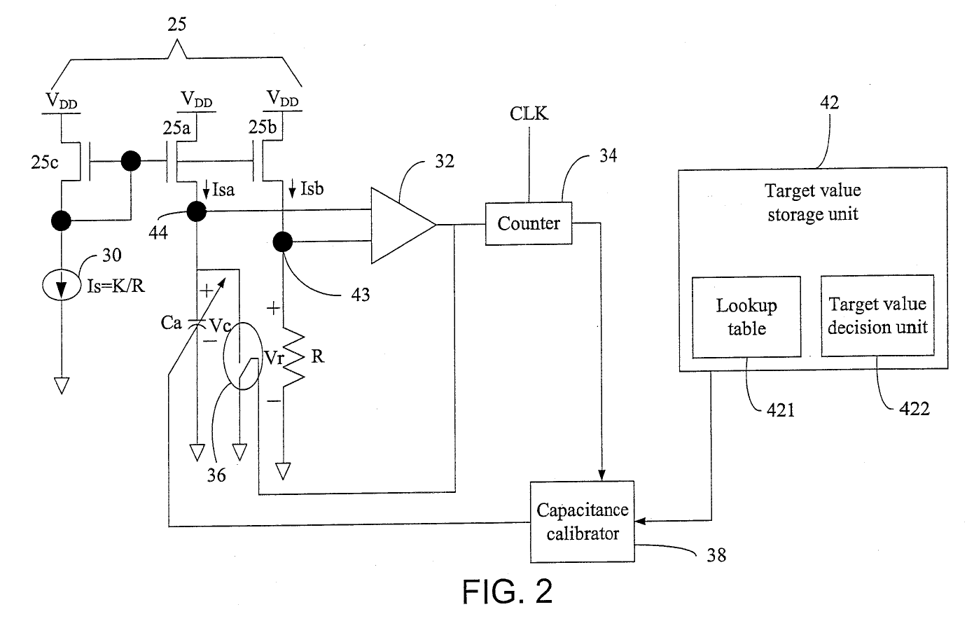

FIG. 2 shows a circuit diagram of a preferred embodiment of the tuning circuit 20 depicted in FIG. 1. The current source 30 provides a steady current Is (which equals to K/R) based on a bandgap voltage, which is well known in the art, to ensure a consistency and stability over variations in supply voltage and operating temperature. Through replication of the current Is by using the current mirror 25, a value of reference voltage signal Vref at node 43 equals to I_{sb}×R=K/R×b×R=K×b, while current Iₛₐ flowing to an variable capacitor Ca equals to Iₛₐ=K/R×a, where factors a, b indicate current replication ratios of MOSFETs 25a, 25b relative to MOSFET 25c, respectively.

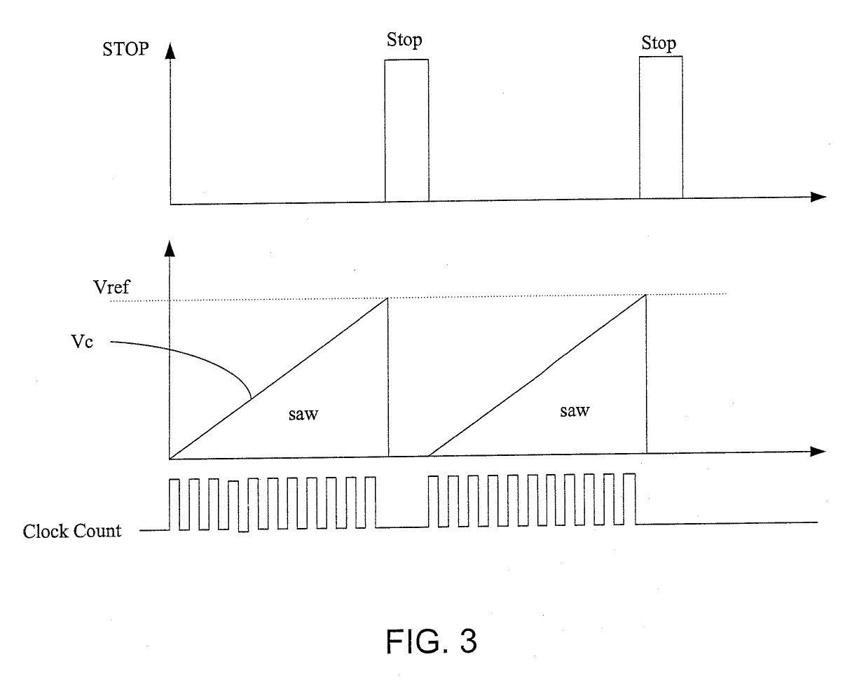

In conjunction with FIG. 2, FIG. 3 illustrates a timing diagram associated with reference voltage signal Vref and voltage at node 44 depicted in FIG. 2. A comparator 32 compares the DC reference voltage signal Vr with voltage drop Vc across the capacitor Ca which rises as the current Iₛₐ charges the capacitor Ca. In the meantime, a counter 34 is enabled based on a system clock signal CLK connected thereto. During the time period Tsaw which the counter 34 is enabled, the counter 34 counts the number of pulses of the system clock signal CLK. When reference voltage signal Vr matches the value of rising voltage drop Vc, the comparator 32 sends a stop signal STOP (as shown in FIG. 3) to the counter 34 to stop counting, and to a switch 36 (can be implemented by a MOSFET) to form a discharge route for the capacitor Ca. When receiving stop signal STOP, the switch 36 turns on and thus the capacitor Ca discharges. In a time period Tsaw of charging the capacitor Ca, charge Q accumulated in the variable capacitor Ca can be expressed as:

Q=Tsaw×Isa=Tsaw×K/R×a=C×Vc=C×K×b,

where factor C indicates capacitance of the capacitor Ca. Therefore, a measured time period Tsaw of charging the capacitor Ca is concluded as a function of Tsaw==C×R×b/a. For the system clock signal CLK is a conformed and stable signal, the measured time period Tsaw is precisely obtained by counting the number of pulses N which are counted by the counter 34. In other words, once an output of the counter 34 which is represented as Tsaw/Tclock (where the factor Tclock means a cycle of the system clock) is obtained, the measured time period Tsaw is obtained as well.

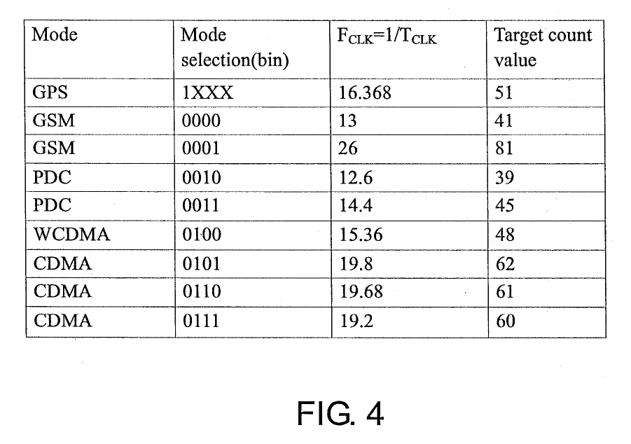

With reference to FIGS. 1, 2, 3 and 6, the measured RC time constant of the active filter 20 is accordingly obtained resulting from provided factors Tsaw, a and b. Upon receiving the output of the counter 34 which indicates the measured time period Tsaw, the capacitance calibrator 38 can adjust the capacitance of the variable capacitor Ca to comply with the desired RC time constant based on a difference between a target count value and the measured count value N. A target value storage unit 42 determines the target count value. The target value storage unit 42 contains a lookup table 421 for storing a plurality of pulse values of the clock signals and a plurality of target count values corresponding to the plurality of pulse values of the clock signals, and a target value decision unit 422 for determining the target count value corresponding to the pulse of the clock signal from the lookup table 421. Referring to FIG. 4, which is an example of a lookup table 421 illustrating a relationship of clock frequency and target count value for various communication systems, the target value decision unit 422 is capable of selecting a corresponding target count value and the clock signal CLK from the lookup table 421. As an example, if detecting a mode selection signal of logical value “0001”, the target value decision unit 422 determines the frequency of a clock signal of 26 MHz and a target count value of 81, and delivers them to the capacitance calibrator 38. In other embodiment, the employment of the counter 34 can be replaced by a timer for timing the time period over which the capacitor Ca is charging, while the lookup table 421 can store a plurality of target time periods indicative of the above-mentioned target count values. So the capacitance calibrator 38 can also adjust the capacitance of the variable capacitor Ca to comply with the desired RC time constant based on a difference between the target time period and the measured time period Tsaw, instead of the target count value and the measured count value N.

As a result, by using the above-mentioned mechanism, the RC time constant deviation is easily and precisely obtained. For example, if the system clock signal CLK with a time period of 50 ms is given, and the RC time constant of the active filter of 1000 ms is desired. When a number of the pulses of the system clock signal CLK which are counted by the counter 34 equals to 49, this means a measured RC time constant (that is, a product of resistance of resistor R and capacitance of capacitor Ca) of the active filter may be 950 ms inconsistent with the desired RC time constant of 1000 ms. Hence, the capacitance of the capacitor Ca can be raised so that the product of resistance of resistor R and capacitance of capacitor Ca matches the desired RC time constant of 1000 ms.

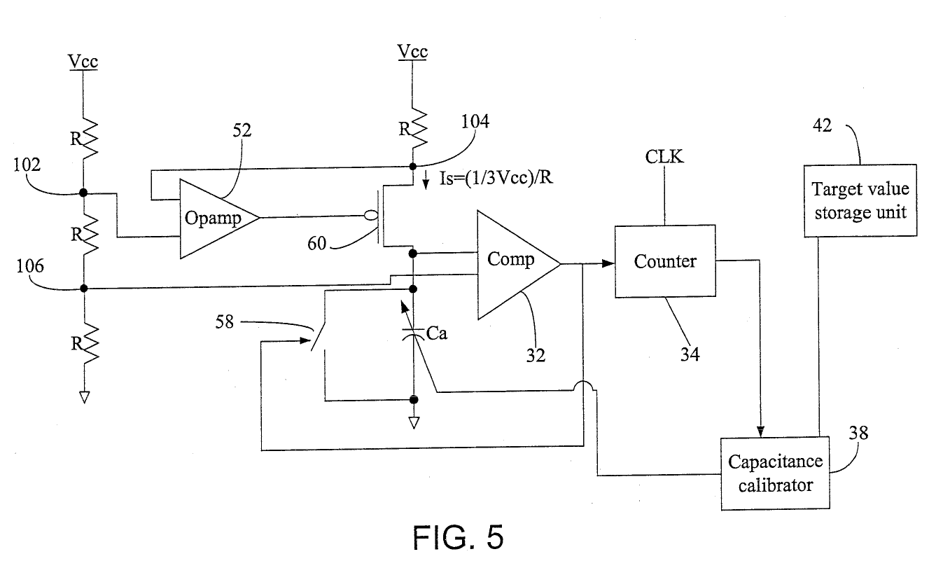

In conjunction to FIG. 2, FIG. 5 shows another embodiment of tuning circuit 50 in accordance with the present invention. It is noted that, for simplicity, elements in FIG. 5 that have the same function as that illustrated in FIG. 2 are provided with the same item numbers as those used in FIG. 2. Differing from FIG. 2, this embodiment uses a DC voltage dividing circuit and an operational amplifier 52 in lieu of a current mirror. Voltage value at node 102 is ⅔×Vcc while voltage value at node 104 is ⅔×Vcc as well due to virtual ground effect of an operational amplifier 52. As the MOSFET 60 conducts, the current Is flowing to a variable capacitor Ca equals to ⅓×Vcc/R, while a value of reference voltage signal at node 104 equals to ⅔×Vcc. A comparator 32 compares the DC voltage signal Vref of ⅓×Vcc with voltage drop Vc across the capacitor Ca which rises as the current Is charges the capacitor Ca. In the meantime, a counter 34 is enabled based on a system clock signal CLK connected thereto. During the time period Tsaw which the counter 34 is enabled, the counter 34 counts the number of pulses of the system clock signal CLK. When reference voltage signal Vref matches the value of rising voltage drop Vc, the comparator 32 generates a stop signal STOP (as can be seen in FIG. 3) to the counter 34 to stop counting, and to a switch 58 (can be implemented by a MOSFET) to form a discharge route for the capacitor Ca. When receiving stop signal STOP, the switch 58 turns on and thus the capacitor Ca discharges. In a time period Tsaw of charging the capacitor Ca, charge Q accumulated in the variable capacitor Ca can be expressed as:

Q=Tsaw×Is=Tsaw×⅓×Vcc/R=C×Vc=C×⅓×Vcc,

where factor C indicates capacitance of the capacitor Ca.

Therefore, a time period Tsaw of charging the capacitor Ca is concluded as a function of Tsaw=C×R. Due to the system clock signal CLK is a conformed and stable signal, the time period Tsaw is precisely obtained by counting the number of pulses which are counted by the counter 34. In other words, once an output of the counter 34 which is represented as Tsaw/Tclock, where the factor Tclock means a time period of the system clock is obtained, and the time period Tsaw is also obtained. In this way, the RC time constant of the measured active filter 20 is obtained resulting from the provided factor Tsaw. It should be noted that even if the bias Vcc may be different values for different ICs (e.g. one is operated at 2.9 Volts, yet another one is operated at 2.8 volts), the RC time constant is irrelevant to the bias voltage Vcc. So the RC time constant deviation is easily and precisely obtained. Finally, as described above, the counter 34, the target value storage unit 42 and the capacitance calibrator 38 performs the same function to tune the active filter 20.

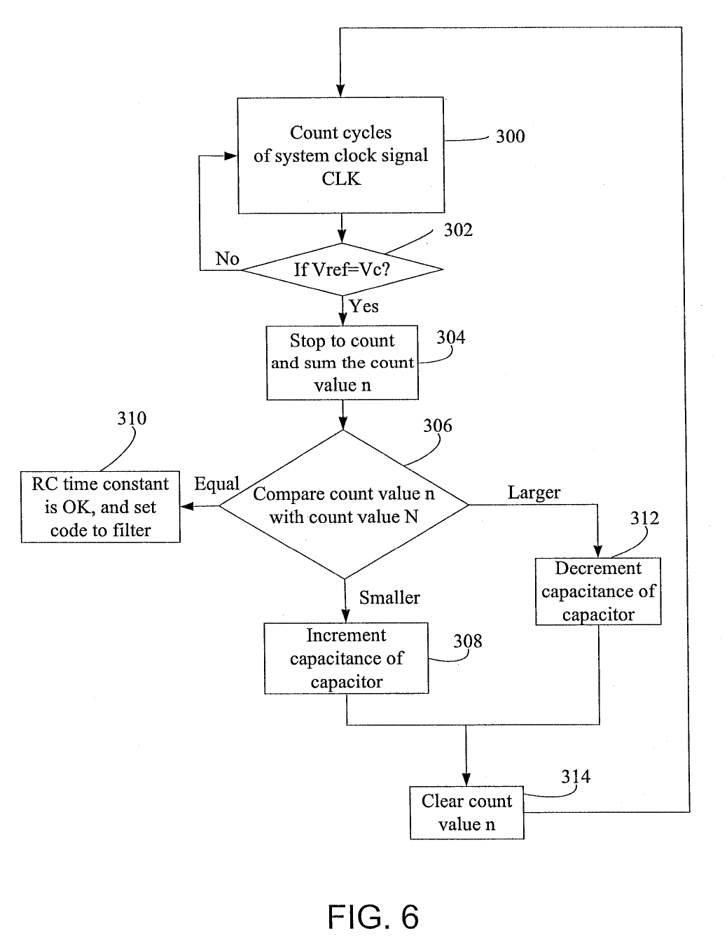

Referring to FIG. 6, as shown is a flowchart of tuning the RC time constant according to the present invention. First of all, in step 300, until a value Vref of the DC reference signal equals to voltage drop Vc across the variable capacitor Ca, counts pulses of system clock signal CLK. Upon reaching such criteria of the DC reference signal Vref consistent with the voltage drop Vc across the variable capacitor Ca, stop counting and sum the count number n. As illustrated in step 306, if the count value n is not equal to a target count value N which is defined by the desired RC time constant of the active filter, i.e. the measured capacitance has error relative to the desired capacitance, set a new capacitance for the capacitor Ca. If the count value n is larger than the target count value N, decrement capacitance of the variable capacitor (step 312). If the count value n is larger than the target count value N, increment capacitance of the variable capacitor Ca (step 308). After clearing the count value n, repeat step 300. The new capacitance leads to a new count value n due to a change of RC product. Until the new count value n equals the target count value N, the calibration process is completed, indicating that a product of the new capacitance and the resistance of the resistor complies with the desired RC time constant. As a result, the new capacitance code is set to the filter to adjust capacitance of capacitor accordingly (Step 310).

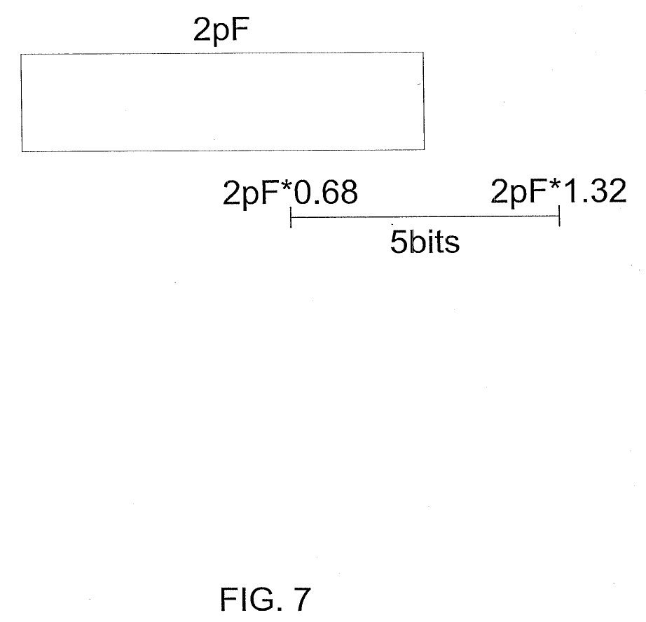

Referring to FIG. 7, as shown is an example of a nominal design capacitance of a variable capacitor. Assume that the variable capacitor with a ±32% tuning variation which can be digitally represented within 5 bits has a nominal capacitance of 2 pF. This means that a Least Significant Bit (LSB) of tuning bits is indicative of 40 fF (2 pf*0.64/2⁵). Accordingly, the capacitance of the variable capacitor can be digitally adjusted to achieve RC compensation in an approximate range of ±32%. Certainly, as the one skilled in the art is aware, any other range may be selected in conformance with the application for which the active filter circuit is used. In addition, the whole calibration mechanism is to utilize successively approximating the capacitance of the capacitor to comply with the predetermined RC time constant.

In contrast to prior art, the present invention utilizes a comparison of a DC reference voltage and an AC voltage across a variable capacitor to determine an actual RC time constant of an active filter. Then, the measured RC time constant of the filter is compared with a predetermined RC time constant and is converged on it. The variable capacitor is adjusted to keep the filter circuit within a desired RC range. Due to the use of passive resistors instead of MOSFETs, the filter is highly linear. Moreover, the RC time constant of the filter is determined by a digital code provided to the tuning circuit. Although the accuracy of the RC time constant is limited by the number of bits of the digital code, and the nominal value of the LSB of the variable capacitor, a range of +/−32% for the corner frequency of the filter is sufficient for many low to medium frequency applications.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A method of tuning an RC time constant comprising:
providing a predetermined time period value associated with a predetermined RC time constant;
providing a first signal;
generating a second signal responsive to charging a capacitor until magnitudes of the second signal and the first signal are matched;
determining a time period charging the capacitor; and
adjusting a capacitance of the capacitor to comply with the predetermined RC time constant based on the time period and the predetermined time period value.

2. The method of claim 1 further comprising:
discharging the capacitor after magnitudes of the second signal and the first signal are matched.

3. The method of claim 1, wherein the step of adjusting a capacitance of the capacitor to comply with the predetermined RC time constant based on the time period and the predetermined time period value comprises successively approximating the capacitance of the capacitor to comply with the predetermined RC time constant.

4. The method of claim 1, wherein the step of determining a time period charging the capacitor comprises counting an amount of pulses of a clock signal.

5. The method of claim 4 further comprising determining the predetermined time period value from a plurality of predetermined time period values stored in a lookup table.

6. The method of claim 1, wherein the predetermined time period value is a target count value related to a cycle of a clock signal.

7. The method of claim 6 further comprising determining the target count value and the related cycle of a clock signal from a plurality of predetermined target count values and a plurality of cycles of clock signals stored in a lookup table.

8. A tuning circuit for tuning an active filter comprising:
a signal generator for generating a first signal and a second signal in proportion to the first signal;
a variable capacitor;
a comparator for comparing a charging voltage with the second signal, wherein a steady current generated based on the first signal serves to charge the variable capacitor to vary the charging voltage;
a period determining unit for determining a time period during which the variable capacitor is charged, until the charging voltage matches the magnitude of the second signal;
a target value storage unit for storing a target time period; and
a capacitance calibrator for calibrating a capacitance of the variable capacitor based on the time period and the target time period.

9. The tuning circuit of claim 8 further comprising:
a switch, bypass with the variable capacitor, for forming a discharge route for the variable capacitor if the charging voltage matches the magnitude of the second signal.

10. The tuning circuit of claim 8, wherein the period determining unit comprises a counter for counting an amount of pulses of a clock signal to determine the time period.

11. The tuning circuit of claim 10, wherein the target value storage unit stores a target count value associated with the target time period.

12. The tuning circuit of claim 11, wherein the target value storage unit further comprising:
a lookup table for storing a plurality of cycles of the clock signals and a plurality of target count values corresponding to the plurality of cycles of the clock signals; and
a target value decision unit for determining the target count value corresponding to the cycle of the clock signal from the lookup table.

13. The tuning circuit of claim 10, wherein the capacitance calibrator is used for digitally adjusting the capacitance of the variable capacitor based on the amount of pulses of the clock signal.

14. The tuning circuit of claim 10, wherein the capacitance calibrator is used for successively approximating the capacitance of the variable capacitor based on the amount of pulses of the clock signal.

15. The tuning circuit of claim 8, wherein the signal generator comprises:
a steady current source for providing a steady DC current based on a bandgap voltage; and
a current mirror for replicating the steady DC current generated by the steady current source to provide the first and second signals.

16. The tuning circuit of claim 8, wherein the signal generator comprises a voltage dividing circuit for dividing a DC voltage into the first signal and the second signal.

17. The tuning circuit of claim 16, wherein the signal generator comprises:
a transistor having a gate electrode, a source electrode, and a drain electrode coupled to the variable capacitor; and
an operational amplifier comprising an output end coupled to the gate electrode, a first input end coupled to the first signal, and a second input end coupled to the source electrode.

18. A method for tuning an RC time constant, the method comprising:
providing a steady current to charge a capacitor to a reference voltage;
determining a time period charging the capacitor for the reference voltage; and
adjusting a capacitance of the capacitor based on the time period; and
wherein the time period is proportional to the RC time constant.

19. The method of claim 18, wherein the step of determining a time period charging the capacitor for the reference voltage comprises counting an amount of pulses of a clock signal.

20. The method of claim 19, further comprising:
comparing the amount of pulses of a clock signal with a predetermined RC time value corresponding to the RC time constant, prior to the step of adjusting a capacitance of the capacitor based on the time period.
